(19) United States
(12) Patent Application Publication
(10) Pub. No.: US 2006/0187728 A1
(43) Pub. Date: Aug. 24, 2006

(54) Integrated semiconductor memory

(76) Inventors: Fabien Funfrock, Muenchen (DE); Michael Bernhard Sommer, Raubling (DE)

Correspondence Address: SLATER & MATSIL LLP, 17950 PRESTON ROAD, SUITE 1000, DALLAS, TX, 75252, US

(21) Appl. No.: 11/238,625

(22) Filed: Sep. 29, 2005

(30) Foreign Application Priority Data
Sep. 29, 2004 (DE) 10 2004 047 331.5

(51) Int. Cl. G11C 7/00

(52) U.S. Cl. 365/203

(57) ABSTRACT

An integrated semiconductor memory (100) comprises a controllable voltage generator (30) for precharging bit lines (BL) of a memory cell array (10) to a precharge voltage (VEQ). During the read-out of a first and second memory state of memory cells (SZ) which are connected to the bit lines, a first and second signal swing (ΔUH, ΔUL) occurs on the bit lines, as a result of which the bit lines are charged to a first and a second voltage potential (V1, V2). For the purpose of precharging the bit lines to the precharge voltage (VEQ), a first equalize current (I1) and a second equalize current (I2) are fed onto the bit lines by the controllable voltage generator (30), the current intensity of said currents in each case being measured by a detector circuit (60). A control circuit (20) alters the precharge voltage (VEQ) until the first and second equalize currents (I1, I2) have identical magnitudes. The precharge voltage is then centered with respect to the first and second voltage potentials (V1, V2).

This application claims priority to German Patent Application 10 2004 047 331.5, which was filed Sep. 29, 2004, and is incorporated herein by reference.

### TECHNICAL FIELD

The invention relates to an integrated semiconductor memory with a variable precharge voltage.

### BACKGROUND

Integrated semiconductor memories, for example DRAM (dynamic random access memory) semiconductor memories, have voltage generators for generating internal voltages. Such voltage generators have the task of generating stabilized voltages from externally applied voltages. The stabilized voltages are to be made available to circuit components of the integrated semiconductor memory, thereby ensuring entirely satisfactory operation of the semiconductor memory.

FIG. 4 shows an integrated semiconductor memory 100 comprising a memory cell array 10, in which memory cells SZ are arranged along word lines WL and bit lines BL. The bit lines BL are in each case connected to a primary sense amplifier SA. The primary sense amplifiers SA that are respectively connected to the bit lines are in turn connected to a secondary sense amplifier SSA. The secondary sense amplifier SSA is connected to a data terminal DQ of the integrated semiconductor memory. Furthermore, the integrated semiconductor memory 100 comprises a control circuit 20, which controls write and read accesses to the memory cells of the memory cell array 10. For the selection of a memory cell SZ, an address signal AS is applied to an address terminal A40, the address signal being fed to an address register 40. The address of a selected memory cell is buffer-stored in the address register 40 and fed to the control circuit 20 for activation of the corresponding memory cell.

In order to generate internal voltages, the integrated semiconductor memory has voltage generators, of which a voltage generator 30 for generating a precharge voltage VEQ is illustrated by way of example. The voltage generator 30 comprises a supply terminal V30 for application of a supply voltage VDD and a reference terminal B30 for application of a reference voltage VSS. The supply voltage VDD and the reference voltage VSS are fed to the voltage generator 30 from an external supply terminal V100 of the integrated semiconductor memory for application of the supply voltage VDD and from an external reference voltage terminal B100 for application of the reference voltage VSS.

FIG. 5 shows the voltage generator 30 and also an excerpt from the memory cell array 10 in an enlarged illustration. For reasons of better clarity, only one sense amplifier SA is illustrated within the memory cell array 10, this sense amplifier being connected to a bit line pair comprising the bit lines BL and /BL. A DRAM memory cell SZ comprising a selection transistor AT and a storage capacitor SC is connected to the bit line BL. Arranged between the bit lines BL and /BL is a precharge circuit EC for precharging the two bit lines to the precharge potential VEQ generated by the voltage generator 30. The precharge circuit EC comprises three switching transistors Tr1, Tr2 and Tr3. The transistor Tr1 serves for short-circuiting the bit line BL with its complementary bit line /BL. The bit line BL and its complementary bit line /BL can be charged to the precharge voltage VEQ via the transistors Tr2 and Tr3.

FIG. 6 shows the voltage profiles on the bit line BL and the complementary bit line /BL in the event of a read access to the memory cell SZ. Prior to the instant T1, the bit lines BL and /BL are charged to the precharge voltage VEQ. For this purpose, the control circuit 20 drives the control terminals of the transistors Tr1, Tr2 and Tr3 of the precharge circuit EC with a high voltage potential VP. The transistors Tr1, Tr2 and Tr3 are designed as n-channel field effect transistors and are controlled into the on state by the high level of the control voltage VP. The two bit lines BL and /BL are conductively connected to one another via the transistor Tr1 and are in each case charged to the precharge voltage VEQ via the transistors Tr2 and Tr3. If it is assumed that the bit line capacitance C_{BL} of the bit line BL and the bit line capacitance C/_{BL} of the bit line /BL are identical, a charge equalization takes place between the two bit lines of the bit line pair until both bit lines have assumed the precharge voltage VEQ.

At the instant T1, an address signal AS is applied to the address terminal A40 of the address register 40 and an activation signal ACT is applied to a control terminal S20a of the control circuit 20. The control circuit 20 consequently deactivates the precharge circuit EC by turning off the switching transistors Tr1, Tr2 and Tr3. The memory cell SZ selected by means of the address signal AS is activated, by contrast, by the word line WL that is connected to a control terminal of the selection transistor AT of the selected memory cell SZ being driven with a high voltage potential VPP, which controls the selection transistor AT into the on state. The storage capacitor SC is thereby conductively connected to the bit line BL connected to the selected memory cell SZ.

FIG. 6 illustrates the case in which a first memory state, for example a high level, was stored in the memory cell SZ. For this purpose, the storage capacitor SC is charged to a voltage lying above the precharge voltage VEQ. The conductive connection of the storage capacitor to the bit line BL gives rise, on the latter, to a signal swing ΔUH, which brings about a potential increase to the voltage potential V1 lying above the precharge voltage VEQ. After a signal development time has elapsed, the primary sense amplifier SA amplifies the voltage levels on the bit line BL and the complementary bit line /BL at the instant T2. The bit line pair is “spread” by virtue of the bit line BL being charged to the high voltage potential VBH and the bit line /BL being charged to the low voltage potential VBL of the spread bit line pair. At the instant T3, a read command RD is applied to the control terminal S20a of the control circuit 20. As a result, the high voltage level VBH corresponding to the high level stored in the memory cell SZ is once again amplified by the secondary sense amplifier SSA and output to the data terminal DQ. At the instant T4, the control terminal S20a of the control circuit 20 is driven with a precharge command PRE. The control circuit 20 thereupon controls the selection transistor AT into the off state again by applying a negative voltage potential VNW on the word line WL. At the same time, the switching transistors Tr1, Tr2 and Tr3 are controlled into the on state again by the control signal VP, so that a charge equalization to the precharge voltage VEQ takes place between the bit lines BL and /BL.

If a low state was stored in the memory cell SZ, a potential decrease occurs on the bit line BL after the selection transistor of the memory cell has been controlled into the on state. As in the case of reading out the high state, here as well the sense amplifier SA amplifies the voltage difference between the voltage decrease on the bit line BL and the precharge voltage VEQ on the complementary bit line /BL.

When reading out both memory states of the memory cell SZ, therefore, a voltage difference, the signal swing, occurs between the bit line BL and the complementary bit line /BL and has to be detected by the sense amplifier SA. In order to ensure a secured read-out of the cell content, the signal increase when reading out a high state and the signal decrease when reading out a low state should be identical. If, by contrast, the signal swing turns out to be too small, after the driving of the control circuit 20 with the activation signal ACT, for the read-out of the high state or for the read-out of the low state, then the voltage difference can no longer be reliably detected by the sense amplifier SA. An erroneous read-out of the memory state of the selected memory cell is the consequence. Therefore, when reading out the high state and when reading out the low state, the signal swing should be identical with respect to the precharge voltage and be of sufficient magnitude.

The precharge voltage VEQ has hitherto been determined by means of the mean value of the high voltage potential VBH and the low voltage potential VBL of the spread bit lines. Since the low voltage potential VBL generally matches the ground potential, the halved level of the high voltage potential VBH has been chosen as the level of the precharge voltage VEQ.

Nevertheless, it is often found that the signal swing ΔUH established when reading out a high memory state differs from the signal swing ΔUL established when reading out the low memory state. FIG. 7 shows corresponding voltage diagrams in this respect. In FIG. 7, the voltage potential V1 established on the bit line BL when reading out the high level has turned out to be smaller, for example, than the voltage potential V2 established on the bit line BL when reading out the low state. The different signal swing arises for example by virtue of the fact that the selection transistor cannot be controlled sufficiently into the on state in the case where a high voltage level corresponding to the high memory state is read out. On account of this, the signal swing ΔUH on the bit line turns out to be too small to still be reliably detected by the sense amplifier SA. It may likewise happen that the signal swing ΔUL when reading out the low memory state turns out to be too small. The cause of this is predominantly a subthreshold current that flows into the memory cell SZ despite the selection transistor being controlled into the off state. The storage capacitor SC is thereby gradually charged to the level of the precharge voltage VEQ within the precharge phase.

### SUMMARY OF THE INVENTION

In one aspect, the present invention specifies an integrated semiconductor memory in which the precharge voltage is variable, so that the signal swings established on a bit line when reading out a memory state of a memory cell coupled to the corresponding bit line turn out to be of sufficient magnitude and approximately identical with respect to the altered precharge voltage. In a further aspect, the present invention specifies a method by means of which the precharge voltage can be altered in such a way that the signal swings established on a bit line when reading out a memory state of a memory cell connected to the corresponding bit line turn out to be of sufficient magnitude and approximately identical with respect to the altered precharge voltage.

In a preferred embodiment, an integrated semiconductor memory includes a memory cell coupled to a bit line, and in which the bit line, for the purpose of charging to a precharge voltage, can be coupled to a terminal for application of the precharge voltage. The integrated semiconductor memory furthermore includes a control circuit for generating a control signal and a controllable voltage generator with an input terminal for application of the control signal generated by the control circuit and with an output terminal for generating the precharge voltage. The controllable voltage generator is designed in such a way that it generates the precharge voltage on the output side in a manner dependent on the control signal. The integrated semiconductor memory furthermore contains a detector circuit for measuring an equalize current between the output terminal of the controllable voltage generator and the terminal for application of the precharge voltage. The equalize current measured by the detector circuit can be fed to the control circuit. The control circuit is designed in such a way that it generates the control signal for driving the controllable voltage generator in a manner dependent on the magnitude of the measured equalize current.

In one development of the integrated semiconductor memory, the controllable voltage generator includes a further input terminal for application of an actual value of the precharge voltage. The terminal for application of the precharge voltage is connected to the further input terminal of the controllable voltage generator. A desired value of the precharge voltage can be fed to the controllable voltage generator by means of the control signal. The controllable voltage generator is designed in such a way that it generates the equalize current at its output terminal in a manner dependent on the actual value and the desired value of the precharge voltage.

In a further embodiment, the control circuit includes a first storage register and a second storage register. The magnitude of the equalize current measured by the detector circuit can in each case be stored in the first and second storage registers.

In accordance with a further embodiment, a first and a second memory state can be stored in the memory cell. The bit line assumes a first voltage potential when the first memory state of the memory cell is read out, and a second voltage potential when the second memory state of the memory cell is read out. The controllable voltage generator is designed in such a way that it generates a first equalize current for precharging the bit line from the first voltage potential to the precharge voltage and generates a second equalize current for precharging the bit line from the second voltage potential to the precharge voltage. The control circuit is designed in such a way that it stores the magnitude of the first equalize current measured by the detector circuit in the first storage register and the magnitude of the second equalize current measured by the detector circuit in the second storage register.

In another embodiment variant, the control circuit of the integrated semiconductor memory has a comparator circuit. The magnitude of the first equalize current stored in the first storage register and the magnitude of the second equalize current stored in the second storage register can be fed to the comparator circuit. The comparator circuit is designed in such a way that it evaluates the magnitude of the first equalize current and the magnitude of the second equalize current and generates a level of the control signal in a manner dependent on the magnitude of the first and second equalize currents.

In a further refinement of the integrated semiconductor memory, the first voltage potential lies above a level of the precharge voltage and the second voltage potential lies below the level of the precharge voltage. The comparator circuit is designed in such a way that it alters the level of the control signal, so that the controllable voltage generator raises the level of the precharge voltage, if the first equalize current is greater than the second equalize current, and that it alters the level of the control signal, so that the controllable voltage generator lowers the level of the precharge voltage, if the second equalize current is greater than the first equalize current.

Further embodiments relating to the integrated semiconductor memory are described herein.

A method for testing an integrated semiconductor memory provides an integrated semiconductor memory that includes a memory cell for storing a first or a second memory state, which can be connected to a bit line for the purpose of reading its memory state in and out, and a controllable voltage generator, which generates an equalize current for the purpose of precharging the bit line to a desired value of a precharge voltage. A first method step involves storing the first memory state in the memory cell. Afterward, the bit line is precharged to the desired value of the precharge voltage. The memory cell is subsequently connected to the bit line. A first voltage potential is thereupon generated on the bit line. A first equalize current is then generated by the controllable voltage generator for the purpose of precharging the bit line to the desired value of the precharge voltage. The magnitude of the first equalize current is subsequently measured. A subsequent test step involves storing the second memory state in the memory cell. The bit line is thereupon precharged to the desired value of the precharge voltage. The memory cell is subsequently connected to the bit line. A second voltage potential is consequently generated on the bit line. A second equalize current is generated by the controllable voltage generator for the purpose of precharging the bit line to the desired value of the precharge voltage. The magnitude of the second equalize current is subsequently measured. The desired value of the precharge voltage is then altered in a manner dependent on the magnitude of the first and second equalize currents.

In accordance with a further feature of the method for testing the integrated semiconductor memory, the integrated semiconductor memory is provided, the first voltage potential lying above the desired value of the precharge voltage and the second voltage potential lying below the desired value of the precharge voltage. The desired value of the precharge voltage is altered by raising the desired value if the first equalize current is greater than the second equalize current. Furthermore, the desired value of the precharge voltage is altered by lowering the desired value if the second equalize current is greater than the first equalize current.

### BRIEF DESCRIPTION OF THE DRAWINGS

The invention is explained in more detail below with reference to figures showing exemplary embodiments of the present invention. In the figures:

FIG. 1 shows an integrated semiconductor memory with alteration of the precharge voltage according to the invention;

FIG. 2 shows voltage profiles on a bit line pair in the case of alteration of the precharge voltage according to the invention;

FIG. 3 shows voltage potentials on a bit line pair with an altered precharge voltage according to the invention;

FIG. 4 shows an integrated semiconductor memory with generation of a precharge voltage according to the prior art;

FIG. 5 shows a voltage generator for generating a precharge voltage with a memory cell array according to the prior art;

FIG. 6 shows voltage potentials on a bit line pair when reading out a memory state of a memory cell; and

FIG. 7 shows voltage potentials on a bit line pair when reading out different memory states according to the prior art.

The following list of reference symbols can be used in conjunction with the figures:

| | |
|---|---|
| 10 | Memory cell array |
| 20 | Control circuit |
| 21, 22 | Storage register |
| 23 | Comparator circuit |
| 30 | Controllable voltage generator |
| 40 | Address register |
| 50 | First controllable switch |
| 60 | Detector circuit |
| 70 | Storage unit |
| 71 | Fuse element |
| 80 | Second controllable switch |
| 100 | Integrated semiconductor memory |
| A | Output terminal |
| A40 | Address terminal |
| ACT | Activation signal |
| AS | Address signal |
| AT | Selection transistor |
| B | Reference voltage terminal |
| B30 | Reference terminal |
| B100 | External reference voltage terminal |
| BL | Bit line |
| C_{BL} | Capacitance of the bit line |
| DQ | Data terminal |
| E | Input terminal |
| EC | Precharge circuit |
| I | Equalize current |
| MS | Measurement signal |
| PRE | Precharge signal |
| RD | Read signal |
| S | Control signal |
| SA | Primary sense amplifier |
| SC | Storage capacitor |
| SSA | Secondary sense amplifier |
| SZ | Memory cell |
| TM | Test mode signal |
| Tr | Switching transistors |
| ΔU | Signal swing |
| V | Supply voltage terminal |
| V1, V2 | Voltage potential on account of the signal swing |
| V30 | Supply terminal |
| V100 | External supply terminal |
| VBH/VBL | Voltage potential of the spread bit lines |
| VDD | Supply potential |
| VEQ | Precharge voltage |
| VEQS | Desired value of the precharge voltage |
| VN, VP | Control signals of the precharge circuit |
| VPP/VNW | Control signals of the word line |
| VSS | Reference voltage potential |
| WL | Word line |

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

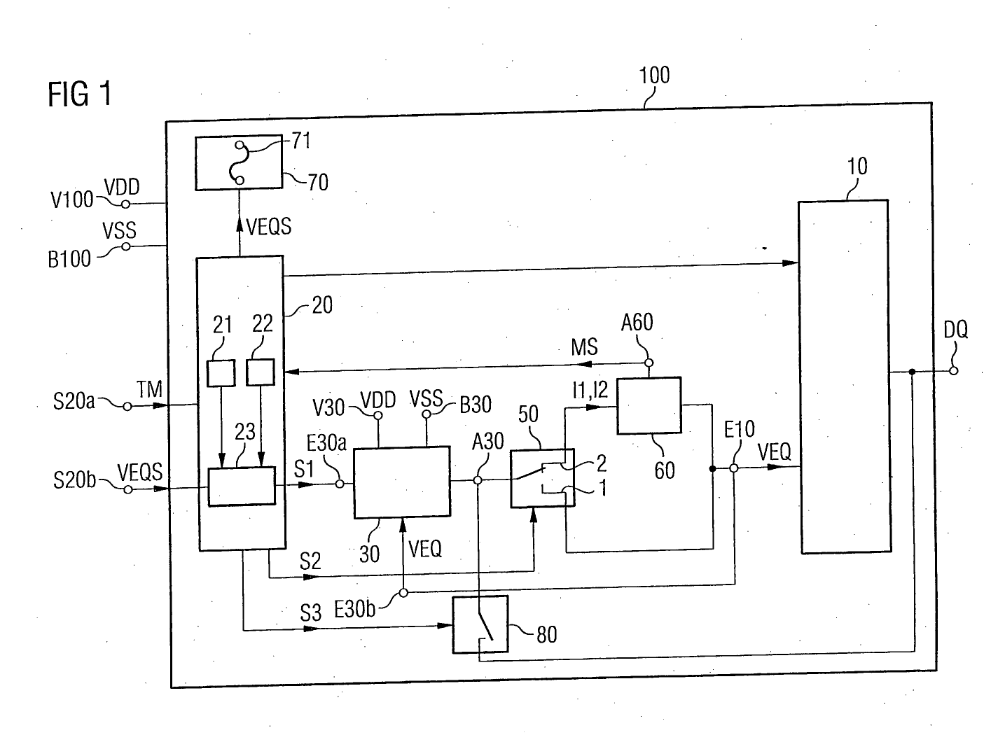

FIG. 1 shows an integrated semiconductor memory 100 with a circuit for altering a precharge voltage VEQ. The integrated semiconductor memory according to a preferred embodiment of the invention includes a memory cell array 10, which is connected to an input terminal E10 for application of the precharge voltage VEQ and to a data terminal DQ for reading data in and out. The integrated semiconductor memory furthermore has a control circuit 20 with a control terminal S20a for application of control signals. The control circuit 20 comprises a first storage register 21 and a second storage register 22. The values that can be stored in the storage registers 21 and 22 are fed to a comparator circuit 23. The comparator circuit 23 generates a control signal S1 on the output side and feeds it to an input terminal E30a of a controllable voltage generator 30.

The controllable voltage generator 30 has a supply terminal V30 for application of a supply voltage VDD and a reference voltage terminal B30 for application of a reference voltage VSS. The controllable voltage generator 30 is fed the supply voltage VDD from an external supply terminal V100 of the integrated semiconductor memory for application of the supply voltage VDD and the reference voltage VSS from an external reference voltage terminal B100 for application of the reference voltage VSS. The controllable voltage generator 30 generates the precharge voltage VEQ at an output terminal A30.

The output terminal A30 is connected to a controllable switch 50. The controllable switch 50 is driven by a control signal S2 from the control circuit 20. Depending on the driving with the control signal S2, the controllable switch 50 can be switched into a first switch position 1 or a second switch position 2. In the first switch position 1, the output terminal A30 of the controllable voltage generator 30 is directly connected to the input terminal E10 for application of the precharge voltage VEQ. In the switch position 2, the output terminal A30 of the controllable voltage generator 30 is connected, via a detector circuit 60 for measuring equalized currents I1 and I2, to the input terminal E10 for application of the precharge voltage VEQ.

The equalize currents are generated by the controllable voltage generator for the purpose of precharging bit lines of the memory cell array 10 to the precharge voltage VEQ and are fed onto the bit lines of the memory cell array 10 via the terminal E10 for application of the precharge voltage. The detector circuit 60 has an output terminal A60 for generating a measurement signal MS. By way of the state of the measurement signal MS, a value of the equalize currents I1 and I2 measured by the detector circuit 60 can in each case be fed to the control circuit 20.

The functioning of the circuit components for altering the precharge voltage VEQ is described below, such that the signal swing when reading out a high memory state and the signal swing when reading out a low memory state on the bit line turn out to be of sufficient magnitude and approximately identical with respect to the level of the precharge voltage VEQ. At the beginning of the test method, the integrated semiconductor memory is switched into a test operating state by the application of a test mode signal TM to the control terminal S20a of the control circuit 20. In the test operating state, the control circuit 20 drives the controllable switch 50 with the control signal S2 in such a way that the controllable switch is switched in the switch position 2. The output terminal A30 of the controllable voltage generator 30 is thus connected via the detector circuit 60 to the input terminal E10 for application of the precharge voltage VEQ.

In order to ascertain the resulting magnitude of the signal swing ΔUH established on the bit line BL when reading out a high memory state, a first memory state is stored in memory cells arranged along a word line of the memory cell array with the high level. The bit lines of the memory cell array are subsequently precharged to the precharge voltage VEQ by the controllable voltage generator 30. In this case, the level of the precharge voltage is produced depending on the state of the control signal S1. The selection transistors of the memory cells of the memory cell array are turned off in the precharge phase. The switching transistors Tr1, Tr2 and Tr3 of the precharge circuit EC are controlled into the on state by driving their control terminals with the control signal VP. When the bit lines are precharged for the first time in this way, the desired value of the precharge voltage that is prescribed by the control circuit 20 preferably lies midway between the high voltage potential VBH and the low voltage potential VBL of the spread bit lines. If the low voltage potential VBL of the spread bit lines corresponds to the ground potential, then the bit lines are charged to the precharge voltage VEQ=VBH/2. The precharge circuit EC is then deactivated again by driving with the control signal VN by virtue of the switching transistors Tr1, Tr2 and Tr3 being turned off.

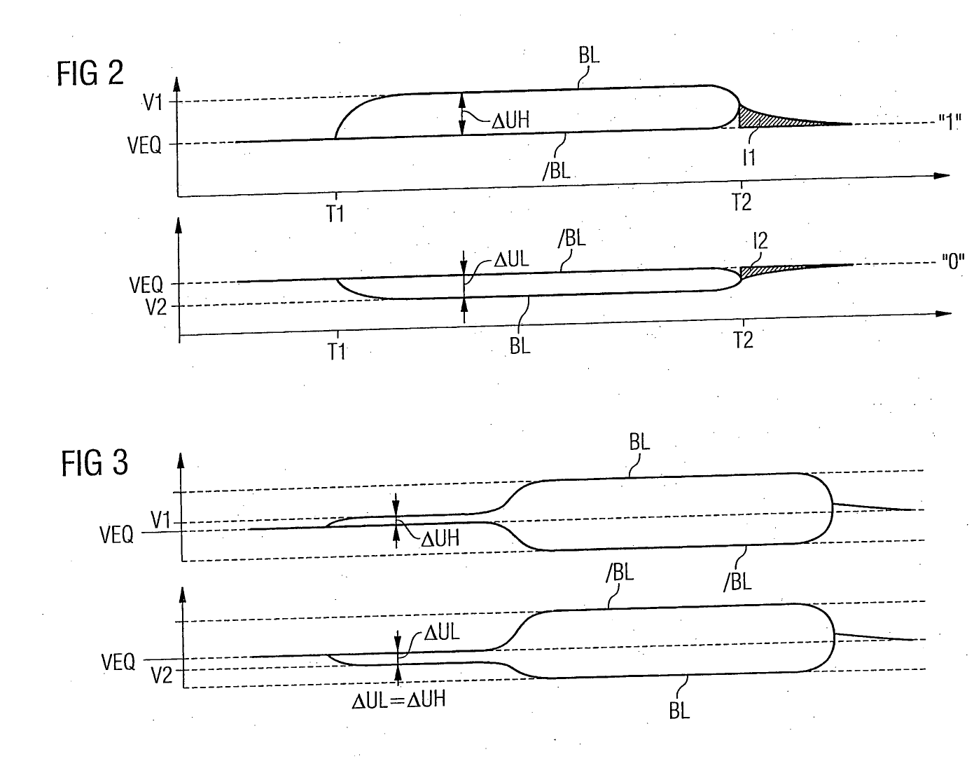

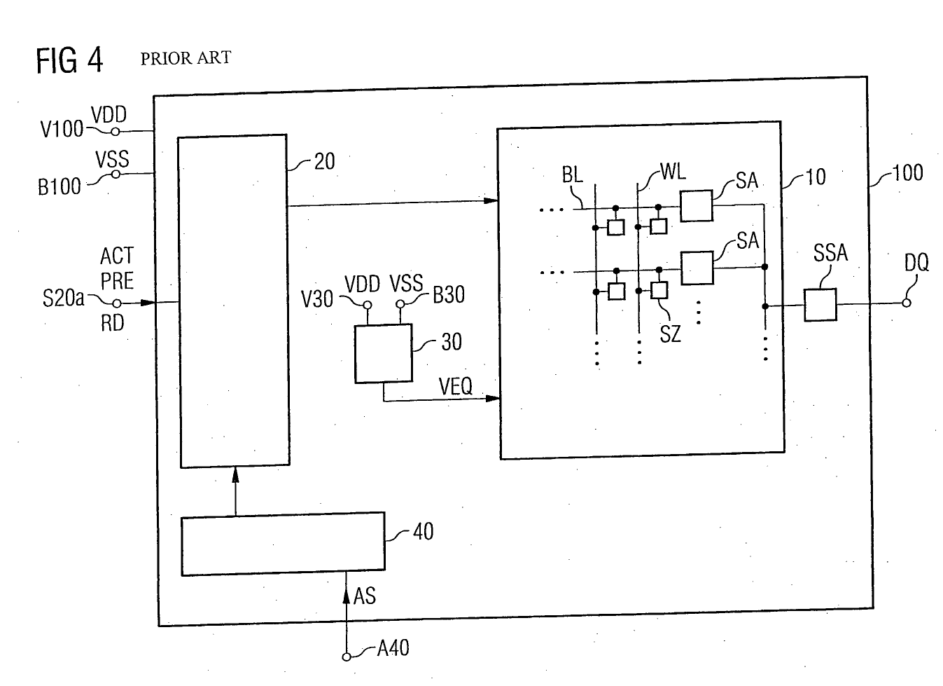

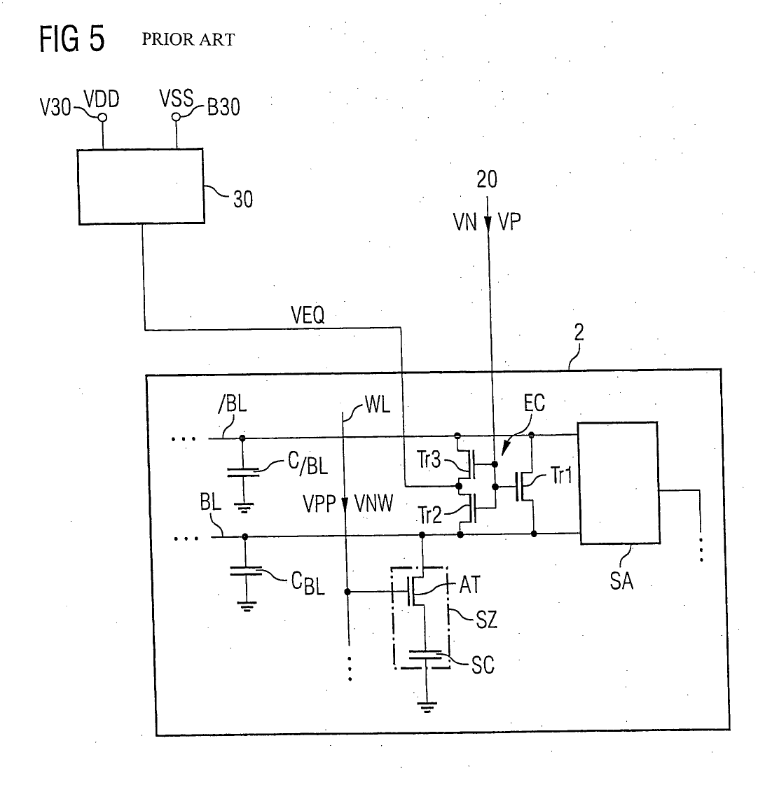

The memory cells connected to the word line are subsequently connected to the respective bit lines for the purpose of reading out their memory state by virtue of the associated selection transistors being controlled into the on state. FIG. 2 shows, in the first diagram, the potential states on a bit line pair whose bit line BL is connected to a memory cell having the high memory state. At the instant T1, the selection transistor of the memory cell is controlled into the on state, so that the voltage potential V1 is established on the bit line as a result of the signal swing ΔUH. The complementary bit line \BL is still charged to the precharge voltage VEQ by the precharge operation prior to the instant T1.

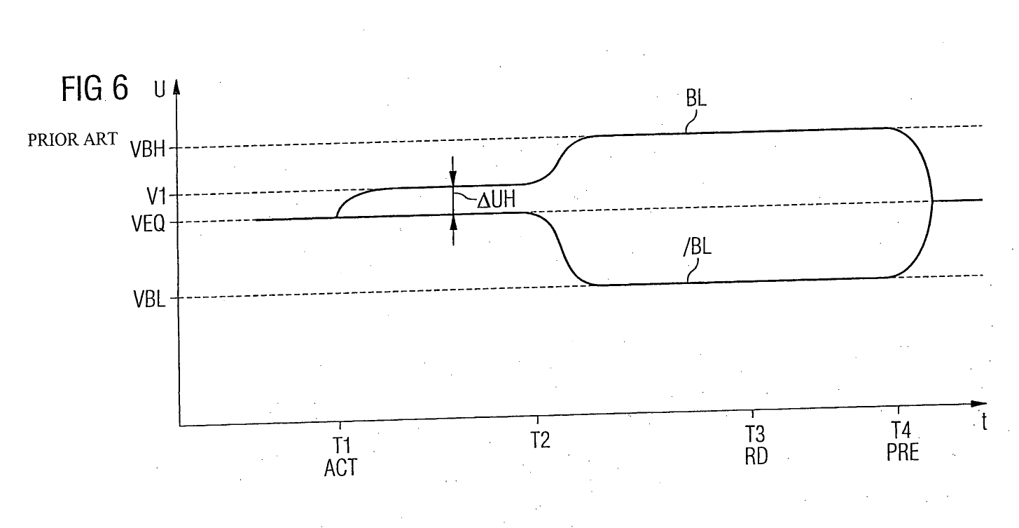

In contrast to the normal operating state, however, at the instant T2, the bit lines BL and /BL are not spread to the high voltage potential VBH and the low voltage potential VBL respectively, as illustrated in FIG. 6. Instead of this, the bit lines are once again precharged to the precharge voltage VEQ. When the bit line BL and the complementary bit line /BL are short-circuited via the switching transistor Tr1 at the instant T2, a center potential lying above the precharge voltage VEQ is established. Therefore, an equalize current I1 flows from the controllable voltage generator 30 onto the bit line pair until the voltage level on both bit lines has again reached the level of the precharge voltage VEQ that is prescribed by the controllable voltage generator 30. The magnitude or the current intensity of the equalize current I1 corresponds to the area illustrated in hatched fashion in the first diagram of FIG. 2. The detector circuit 60 measures the first equalize current I1 and feeds the magnitude of the measured equalize current to the control circuit 20 by means of the measurement signal MS. In the control circuit 20, the magnitude of the equalize current I1 is stored in the storage register 21.

In order to ascertain the way in which the signal swing ΔUL on the bit lines of the memory cell array turns out, which signal swing is established when reading out the low memory state, the second memory state, the low level, is subsequently written to the memory cells along one of the word lines. The second diagram of FIG. 2 shows the voltage levels on a bit line pair whose bit line BL is connected to a memory cell in which the low memory state is stored. After the precharging of the bit lines BL and /BL to the precharge voltage VEQ=VBH/2 prior to the instant T1, the memory cell connected to the bit line BL is activated at the instant T1 by virtue of the associated selection transistor being controlled into the on state. The transistors Tr1, Tr2 and Tr3 of the precharge circuit EC are turned off via the control circuit 20. As shown in the second diagram of FIG. 2, the voltage potential V2 lying below the level of the precharge voltage VEQ is established on the bit line BL as a result of the signal swing ΔUL.

At the instant T2, the selection transistors of the memory cells connected to the word line are turned off again and the precharge circuit EC is activated. The short-circuiting of the bit line BL and its complementary bit line /BL gives rise, on each bit line pair, to a momentary increase in the voltage potential on the bit line BL and a momentary decrease in the voltage potential on the complementary bit line /BL. In order to charge the bit lines to the precharge voltage VEQ prescribed by the controllable voltage generator 30, an equalize current I2 is fed onto the bit line pair illustrated by the controllable voltage generator 30. The current intensity of this equalize current, which corresponds to the area illustrated in hatched fashion in the second diagram of FIG. 2, is likewise measured by the detector circuit 60 and fed to the control circuit 20 by means of the measurement signal MS. In the control circuit 20, the magnitude of the equalize current I2 is stored in the storage register 22.

The comparator circuit 23 subsequently compares the current intensity of the equalize current I1 stored in the storage register 21 with the current intensity of the equalize current I2 stored in the storage register 22. If the current intensities of the two currents have turned out to be identical, the desired value of the precharge voltage that is prescribed by the control circuit 20 corresponds to a level lying centered between the voltage potential V1 and the voltage potential V2. If, by contrast, as is illustrated in FIG. 2, the equalize current I1 has turned out to be greater than the equalize current I2, then the desired value of the precharge voltage that is prescribed by the control circuit 20 is too low. The desired value must therefore be increased in order that the level of the precharge voltage lies centered with respect to the voltage potentials V1 and V2. The comparator circuit 23 will therefore prescribe a higher desired value of the precharge voltage to the controllable voltage generator 30 by altering the state of the control signal S1. The method described is subsequently repeated with the higher precharge voltage.

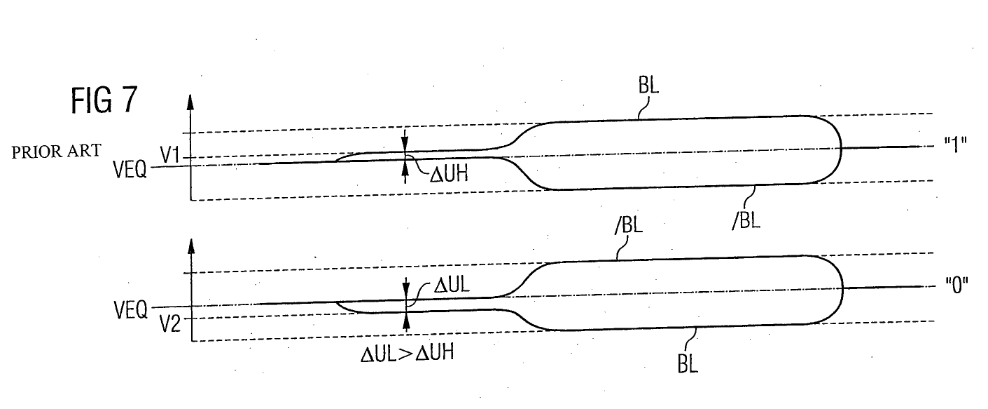

If, by contrast, as was explained in FIG. 7, the signal swing ΔUH when reading out the high memory state has turned out to be smaller than the voltage swing ΔUL when reading out the low memory state, that is to say the equalize current I1 has turned out to be smaller than the equalize current I2, then the comparator circuit 23 will drive the controllable voltage generator 30 with an altered level of the control signal S1, so that the controllable voltage generator 30 generates a lower level of the precharge voltage. The method is subsequently repeated with the lower precharge voltage VEQ.

The precharge voltage VEQ is adapted by the comparator circuit 23 until the current intensity of the equalize current I1 matches the current intensity of the equalize current I2. FIG. 3 shows the altered precharge voltage with respect to the example of FIG. 7, such that the signal swing ΔUH corresponds to the signal swing ΔUL. The altered precharge voltage lies below the original prescribed precharge voltage of FIG. 7.

In order that the equalize currents are not corrupted by local leakage mechanisms of the bit lines, a plurality of equalize currents from a plurality of bit line pairs are preferably superposed simultaneously in parallel and a desired value of the precharge voltage, which lies centered with respect to the voltage potential V1 of the signal swing ΔUH and the voltage potential V2 of the signal swing ΔUL, is determined therefrom.

The desired value of the precharge voltage that is determined is stored in a storage unit 70 by the control circuit 20 and is interrogated by the control circuit 20 upon activation of the integrated semiconductor memory and correspondingly prescribed for the controllable voltage generator 30 for precharging the bit lines of the memory cell array 10. This is advantageous particularly when the integrated semiconductor memory is still in the test state. A final level of the precharge voltage does not yet need to be defined in this phase.

In another embodiment, the desired value that is determined is fed to the data terminal DQ. For this purpose, the control circuit 20 drives a controllable switch 80 with a control signal S3 if the comparator circuit 23 has detected identical equalize currents I1 and I2. As a result of the driving with the control signal S3, the controllable switch 80 is closed and, consequently, the output terminal A30 of the controllable voltage generator 30 is connected to the data terminal DQ. The level of the precharge voltage that is generated by the controllable voltage generator, which level in this case corresponds to the centered level between the voltage potential V1 and the voltage potential V2, can be tapped off at the data terminal DQ of the integrated semiconductor memory by a tester, for example.

The control circuit 20 may have a further control terminal S20b. The desired value VEQS of the precharge voltage can be prescribed externally to this control terminal, for example by the tester, in the test phase of the integrated semiconductor memory.

At the end of the production process of the integrated semiconductor memory, the centered precharge voltage is read out at the data terminal DQ by a production unit and stored irreversibly in the storage unit 70. For this purpose, the storage unit 70 contains fuse elements 71 that are correspondingly programmed by the production unit by irradiation with a laser pulse. The desired value VEQS of the precharge voltage that is stored by means of the fuse process is interrogated by the control circuit 20 during operation of the integrated semiconductor memory and prescribed to the controllable voltage generator 30 as the desired value by means of the corresponding level of the control signal S1.

Although the present invention and its advantages have been described in detail, it should be understood that various changes, substitutions and alterations can be made herein without departing from the spirit and scope of the invention as defined by the appended claims.

What is claimed is:

1. An integrated semiconductor memory comprising:
a memory cell coupled to a bit line, wherein the bit line, for the purpose of charging to a precharge voltage, can be coupled to a terminal for application of the precharge voltage;
a control circuit for providing a control signal at an output;
a controllable voltage generator with an input terminal coupled to the output of the control circuit for the controllable voltage generator including an output terminal for providing the precharge voltage, wherein the controllable voltage generator is designed in such a way that it generates the precharge voltage at the output terminal in a manner dependent on the control signal; and
a detector circuit for measuring an equalize current between the output terminal of the controllable voltage generator and the terminal for application of the precharge voltage, wherein the equalize current measured by the detector circuit can be fed to the control circuit, and wherein the control circuit is designed in such a way that it generates the control signal for driving the controllable voltage generator in a manner dependent on the magnitude of the measured equalize current.

2. The integrated semiconductor memory as claimed in claim 1, wherein:
the controllable voltage generator comprises a further input terminal for application of an actual value of the precharge voltage;
the terminal for application of the precharge voltage is coupled to the further input terminal of the controllable voltage generator;
a desired value of the precharge voltage can be fed to the controllable voltage generator by means of the control signal; and
the controllable voltage generator is designed in such a way that it generates the equalize current at its output terminal in a manner dependent on the actual value and the desired value of the precharge voltage.

3. The integrated semiconductor memory as claimed in claim 1, further comprising:
a first controllable switch, which can be switched into a first switch position and into a second switch position;
wherein the output terminal of the controllable voltage generator is coupled to the terminal for application of the precharge voltage in the first switch position of the first controllable switch with bridging of the detector circuit; and
wherein the output terminal of the controllable voltage generator is connected to the terminal for application of the precharge voltage via the detector circuit in the second switch position of the first controllable switch.

4. The integrated semiconductor memory as claimed in claim 3, wherein:
the integrated semiconductor memory can be operated in a normal operating state and in a test operating state;
the first controllable switch can be controlled into the first switch position or the second switch position by the control circuit;
the control circuit can be driven by a test mode signal at a control terminal;
the control circuit is designed in such a way that it controls the first controllable switch into the first switch position in the normal operating state of the integrated semiconductor memory; and
the control circuit is designed in such a way that, in the case of driving with the test mode signal, it operates the integrated semiconductor memory in the test operating state and, in the test operating state, controls the first controllable switch into the second switch position.

5. The integrated semiconductor memory as claimed in claim 4, wherein the control circuit comprises a first storage register and a second storage register, and wherein the magnitude of the equalize current measured by the detector circuit can be stored in the first and second storage registers.

6. The integrated semiconductor memory as claimed in claim 5, wherein:
a first and a second memory state can be stored in the memory cell;
the bit line assumes a first voltage potential when the first memory state of the memory cell is read out, and a second voltage potential when the second memory state of the memory cell is read out;
the controllable voltage generator is designed in such a way that it generates a first equalize current for precharging the bit line from the first voltage potential to the precharge voltage and generates a second equalize current for precharging the bit line from the second voltage potential to the precharge voltage; and
the control circuit is designed in such a way that it stores the magnitude of the first equalize current measured by the detector circuit in the first storage register and the magnitude of the second equalize current measured by the detector circuit in the second storage register.

7. The integrated semiconductor memory as claimed in claim 6, wherein:
the control circuit includes a comparator circuit;
the magnitude of the first equalize current stored in the first storage register and the magnitude of the second equalize current stored in the second storage register can be fed to the comparator circuit; and
the comparator circuit is designed in such a way that it evaluates the magnitude of the first equalize current and the magnitude of the second equalize current and generates a level of the control signal in a manner dependent on the magnitude of the first and second equalize currents.

8. The integrated semiconductor memory as claimed in claim 7, wherein:
the first voltage potential lies above a level of the precharge voltage and the second voltage potential lies below the level of the precharge voltage; and
the comparator circuit is designed in such a way that it alters the level of the control signal, so that the controllable voltage generator raises the level of the precharge voltage, if the first equalize current is greater than the second equalize current, and that it alters the level of the control signal, so that the controllable voltage generator lowers the level of the precharge voltage, if the second equalize current is greater than the first equalize current.

9. The integrated semiconductor memory as claimed in claim 1, further comprising a storage unit for storing the desired value of the precharge voltage;
wherein a desired value of the precharge voltage can be fed to the control circuit; and
wherein the control circuit is designed in such a way that, in a normal operating state, it drives the controllable voltage generator with the level of the control signal, so that the level of the precharge voltage that is generated by the controllable voltage generator on the output side assumes the desired value of the precharge voltage.

10. The integrated semiconductor memory as claimed in claim 9, wherein the storage unit comprises fuse elements.

11. The integrated semiconductor memory as claimed in claim 9, further comprising:
an output terminal and a second controllable switch;
wherein the output terminal of the controllable voltage generator can be connected to the output terminal of the integrated semiconductor memory via the second controllable switch (80); and
wherein the control circuit is designed in such a way that it controls the second controllable switch into the on state if the first equalize current matches the second equalize current.

12. A method for operating an integrated semiconductor memory, comprising:
providing an integrated semiconductor memory comprising a memory cell for storing a first or a second memory state that can be connected to a bit line for the purpose of reading the first or second memory state in and out, and comprising a controllable voltage generator that generates an equalize current for the purpose of precharging the bit line to a desired value of a precharge voltage;
storing the first memory state in the memory cell;
subsequently precharging the bit line to the desired value of the precharge voltage;
subsequently coupling the memory cell to the bit line and generating a first voltage potential on the bit line;
subsequently generating a first equalize current using the controllable voltage generator for the purpose of precharging the bit line to the desired value of the precharge voltage;
subsequently measuring a magnitude of the first equalize current;
subsequently storing the second memory state in the memory cell;
subsequently precharging the bit line to the desired value of the precharge voltage;
subsequently coupling the memory cell to the bit line and generating a second voltage potential on the bit line;
subsequently generating a second equalize current using the controllable voltage generator for the purpose of precharging the bit line to the desired value of the precharge voltage;
subsequently measuring the magnitude of the second equalize current; and
subsequently altering the desired value of the precharge voltage in a manner dependent on the magnitude of the first and second equalize currents.

13. The method as claimed in claim 12, wherein:
providing the integrated semiconductor memory such that the first voltage potential lies above the desired value of the precharge voltage and the second voltage potential lies below the desired value of the precharge voltage;
altering the desired value of the precharge voltage is accomplished by raising the desired value if the first equalize current is greater than the second equalize current; and
altering the desired value of the precharge voltage is accomplished by lowering the desired value if the second equalize current is greater than the first equalize current.

14. The method as claimed in claim 12, further comprising operating the integrated semiconductor memory in a normal mode after altering the desired value of the precharge voltage.

15. The method as claimed in claim 12, wherein altering the desired value of the precharge voltage comprises lowering the desired value of the precharge voltage.

16. The method as claimed in claim 12, wherein altering the desired value of the precharge voltage comprises raising the desired value of the precharge voltage.

17. The method as claimed in claim 12, further comprising irreversibly storing the altered desired value of the precharge voltage.

18. The method as claimed in claim 17, further comprising operating the integrated semiconductor memory in a normal mode after irreversibly storing the altered desired value of the precharge voltage.

19. The method as claimed in claim 17, wherein irreversibly storing the altered desired value of the precharge voltage comprises changing a state of at least one fuse.
